(19) United States
(12) Patent Application Publication
(10) Pub. No.: US 2025/0125590 A1
(43) Pub. Date: Apr. 17, 2025

(54) FOLDED MULTI-LASER PACKAGE

(71) Applicant: ams-OSRAM International GmbH, Regensburg (DE)

(72) Inventor: Anna BUTSCH, Regensburg (DE)

(73) Assignee: ams-OSRAM International GmbH, Regensburg (DE)

(21) Appl. No.: 18/718,363

(22) PCT Filed: Dec. 7, 2022
(86) PCT No.: PCT/EP2022/084831

§ 371 Date: Jun. 10, 2024

(30) Foreign Application Priority Data
Dec. 7, 2021 (DE) 10 2021 132 134.4

(51) Int. Cl. H01S 5/40; H01S 5/02251; H01S 5/02253; H01S 5/02255

(52) U.S. Cl. CPC H01S 5/4068; H01S 5/02251; H01S 5/02253; H01S 5/02255; H01S 5/4012; H01S 5/4093

(57) ABSTRACT

The invention relates to a laser package comprising a first laser diode for emitting light of a first wavelength and at least one second laser diode for emitting light of a second wavelength. The laser package also comprises a reflector module which is arranged in the beam path of the first and of the at least one second laser diode and which is configured to shape the light emitted by the laser diodes and to deflect it by at least 90° in the direction of an optical fiber with respect to an emission direction of the first and of the at least one second laser diode. The light guide runs essentially parallel to the emission direction and comprises an incoupling structure which is configured to couple the light deflected by the reflector module in the direction of the light guide into the light guide.

The present application is a national stage entry from International Application No. PCT/EP2022/082106, filed on Nov. 16, 2022, published as International Publication No. WO 2023/104457 A1 on Jun. 15, 2023, and claims the priority of German patent application No. 10 2021 132 134.4 dated Dec. 7, 2021, the disclosure content of all of which are hereby incorporated by reference into the present application.

### FIELD

The present invention relates to a laser package, in particular a multi-laser package, with a reduced size, and the use of such a laser package.

### BACKGROUND

Laser packages, and in particular multi-laser packages comprising laser diodes that are configured to emit laser light of different wavelengths, for example red laser light, green laser light, blue laser light and/or laser diodes emitting infrared laser light, for generating and projecting color-superimposed light onto a screen or a display, for example, currently have a relatively large footprint or a relatively large component length due to the optics required for collimation and for superimposing the light. For applications, for example in the consumer sector, in particular for applications or applications in the field of virtual reality (VR) or augmented reality (AR), however, it may be necessary for the laser packages to be particularly compact.

At present, however, no compact solutions are known by means of which the light beams of different colors emitted by a multi-laser package with edge-emitting laser diodes, or the light beams of different colors emitted by various closely adjacent separate laser channels of an edge-emitting laser diode (multi-ridge laser diode) can be superimposed in such a way that the individual beams are not emitted from the laser package laterally offset to each other and projected onto a projection surface, but are homogeneously superimposed. In fact, with conventional optical elements it is currently only possible to image the light beams emitted by the laser facets of the multi-ridge laser diodes laterally offset to each other.

There is therefore a need to provide a laser package, in particular a multi-laser package, with a reduced size and an improved superposition of the light beams emitted by the laser diodes, as well as a use of such a laser package which counter-acts at least one of the aforementioned problems.

### SUMMARY OF THE INVENTION

This need is met by a laser package referred to in claim 1. Claim 17 specifies the features of a use of such a laser package according to the invention. Further embodiments are the subject of the subclaims.

The core idea of the invention is that the laser beams emitted by at least two laser diodes are simultaneously shaped by means of a reflector module and deflected by at least 90° so that they impinge laterally on an optical fiber and are coupled into it. The laser beams are superimposed in the light guide and the superimposed laser beams are decoupled from the laser package via the light guide in a direction opposite to the emission of the laser beams from the laser diodes, i.e. “backwards”. The beam guidance of the laser beams emitted by the laser diodes is folded, so to speak, which reduces the footprint, in particular the component length of the laser package, compared to a serial arrangement of the individual components.

In particular, the reflector module is configured in such a way that it can be used to simultaneously deflect the beam and shape the light, such as focusing or collimating at least one of the two main axes (fast and slow) of the laser light emitted by the respective laser diodes. The shaped or collimated light beams can then be coupled laterally into an optical fiber and superimposed in it. In particular, the laser light emitted by the laser diodes can be directed laterally past the laser diodes onto a light guide by means of the reflector module. The reflector module can also be configured to focus the laser light emitted by the respective laser diodes and image it on a desired surface in the form of partial beams. The surface can be the light guide, an imaging optic or a projection surface. A particular advantage of the reflector module is that it provides a space-saving optical module for simultaneous light shaping and deflection of the laser beams. In addition, the compact or space-saving optical module reduces the number of components in the laser package and therefore also the adjustment effort required.

The light guide, into which the shaped laser beams are coupled, in particular in the form of partial beams, achieves a particularly effective form of beam superposition. The shaped laser beams are coupled into the light guide, in particular laterally, and are then superimposed within the light guide in the direction of propagation of the laser beams in the light guide. For this purpose, the light guide can have an incoupling structure that is configured to couple the light deflected by the reflector module in the direction of the light guide into the light guide. The light decoupling of the superimposed laser beams from the laser package takes place in particular via an interface or a decoupling window at one end of the laser package or light guide and takes place in particular in a direction opposite to the emission direction of the laser beams from the laser diodes.

The beam guidance of the laser beams emitted by the laser diodes is accordingly deflected by approx. 180°, which is why the term folded beam path is used in the context of this application. The footprint, in particular the component length of the laser package, is thus reduced compared to a serial arrangement without folding of the beam path.

According to at least one embodiment, a laser package comprises a first laser diode for emitting light of a first wavelength and at least one second laser diode for emitting light of a second wavelength. In particular, the first laser diode is configured to emit light of a first wavelength, and the at least one second laser diode is configured to emit light of a second wavelength that is different from the first wavelength. The laser package also comprises a reflector module which is arranged in the beam path of the first and the at least one second laser diode, and which is configured to shape the light emitted by the laser diodes and to deflect it by at least 90° in the direction of an optical fiber relative to an emission direction of the first and at least one second laser diode. The light guide runs essentially parallel to the emission direction of the first and at least one second laser diode and is arranged adjacent to them. The light guide also comprises an incoupling structure which is configured to couple the light deflected by the reflector module in the direction of the light guide into the light guide.

According to at least one embodiment, the first and the at least one second laser diode are arranged parallel to each other and emit light of the corresponding wavelength along the same emission direction.

According to at least one embodiment, the emission direction of the laser package is essentially offset by 180° to the emission direction of the first and the at least one second laser diode.

The laser light emitted by the laser diodes is decoupled from the laser package in the opposite direction to the light emission of the laser diodes within the laser package.

According to at least one embodiment, the first and the at least one second laser diode are configured according to a chip-on-submount assembly. The first and the at least one second laser diode are thus arranged on a submount and electrically connected to it, which in turn can be part of the laser package as an interconnected component.

According to at least one embodiment, the reflector module is configured to separately shape and deflect the light emitted by the first and the at least one second laser diode. The beams of the individual laser diodes in the laser package are thus individually shaped by the reflector module and reflected laterally or deflected in the direction of the light guide. The laser beams of the individual laser diodes can therefore hit the light guide at different points.

According to at least one embodiment, the reflector module comprises at least two parabolic sinks. For example, the reflector module can be configured as a metal mirror with individual parabolic sinks for the respective partial beams. The parabolic sinks result in separate concave reflectors with a suitable curvature for shaping the incident laser light. The reflector module can, for example, be produced by a stamping process and thus be in the form of a stamped metal mirror. Alternatively, the reflector module can also be formed by a coated carrier with a corresponding curvature or, for example, by a concave mirror. The carrier and/or the concave mirror can be made of glass, for example.

According to at least one embodiment, the reflector module comprises at least two lenses arranged next to each other, for example anamorphic lenses. The lenses also have a reflective coating on a rear side of the lenses or are in the form of reflective metamaterial lenses. The reflector module can accordingly be formed by a lens system, whereby the lenses each have cylindrical entry or exit curvature surfaces for shaping the light emitted by the laser diodes. A reflective coating can be provided on the back of the lenses to deflect the light emitted by the laser diodes. The lenses can, for example, have a common carrier on which they are arranged or be manufactured in one piece from the same material.

Compared to known laser packages with double lenses (per laser diode) and a deflection prism for deflecting the light emitted by the laser diodes, the reflector module used can save both space and material and therefore costs.

According to at least one embodiment, the laser package comprises a first, a second and a third laser diode. The first laser diode is configured to emit red light, the second laser diode is configured to emit green light and the third laser diode is configured to emit blue light. In particular, the three laser diodes can form a so-called RGB laser package. An RGB laser package can, for example, emit light of the colors red, green and blue as well as any mixed colors. In some embodiments, the laser package can also comprise more than three laser diodes and form an RGB-IR laser package, for example. An RGB-IR laser package can, for example, emit light of the colors red, green, blue and infrared, as well as any mixed colors, such as white.

According to at least one embodiment, the laser package comprises a plurality of laser diodes that at least partially emit light of a different wavelength, but also partially emit light of the same wavelength. The multiple laser diodes can, for example, form an R-GG-B laser package, an RR-GG-BB laser package, an RR-G-BB laser package, an RR-GG-BB-IR laser package, etc., where R stands for a red, G for a green, B for a blue and IR for an infrared laser diode. However, the above examples are not intended to be restrictive, but any other combination of different and similar laser diodes conceivable to a person skilled in the art is possible.

According to at least one embodiment, the first and the at least one second laser diode are each formed by an edge-emitting laser diode. The laser diodes can, for example, be operated in pulsed mode during their intended use. In some embodiments, however, it may also be desirable for them to be operated continuously.

According to at least one embodiment, the first and the at least one second laser diode are each formed by a separate laser channel of a multi-ridge laser diode, in particular an edge-emitting multi-ridge laser diode. The multi-ridge laser diode can have several closely adjacent separate laser channels, each of which emits light of at least a slightly different wave-length. However, it is also conceivable that the laser channels emit light of essentially the same wavelength. In the context of the following application, however, it should also be understood in the case of laser channels that emit light of essentially the same wavelength that this may involve light of a first and a second wavelength.

According to at least one embodiment, the light guide is formed by a planar waveguide. For example, the light guide can be formed by a SOI waveguide (silicon-on-insulator). Accordingly, the waveguide can be made of silicon, for example. Silicon has a refractive index of around 3.5 in the near infrared, whereas the refractive index of silicon dioxide is only around 1.5. It is therefore possible to guide light in a structured silicon layer of an SOI structure by total internal reflection. However, it is also possible to use any other type of known optical waveguide. For example, it can also be a waveguide made of silicon nitride (SiN) or aluminum nitride (AlN).

According to at least one embodiment, the light guide is formed by an integrated planar waveguide or integrated optics, e.g. in the structure of a photonic integrated circuit.

According to at least one embodiment, the light guide comprises several beam combiner elements. Accordingly, the light guide can also be configured in the form of a general light guide, which directs the light emitted by the laser diodes along or by means of the beam combiner elements in a desired direction.

According to at least one embodiment, the light guide comprises at least two separate light paths, for example in the form of two separate planar waveguides. In such a case, the laser light emitted by the first and the at least one second laser diode is each coupled into a separate light path and guided along it. In addition, the light guide comprises one or more directional couplers, by means of which the light from the individual light paths is combined or superimposed before it emerges from the laser package.

According to at least one embodiment, the incoupling structure comprises a coupling grating structure on a surface of the light guide. For example, this may be a photolithographically produced or etched coupling grating structure on the surface of the light guide. This coupling grating can be configured in such a way that the laser beams of the individual laser diodes, which impinge on the light guide at different points, for example, are each coupled laterally into the light guide. The coupled laser beams can then be superimposed within the light guide. Such a coupling grating structure can achieve efficient coupling of the shaped partial beams into the light guide, particularly from the side. The coupling grating structure can, for example, have a large number of periodically arranged and spaced-apart elevations, for example silicon elevations, or be formed by a layer, for example a silicon layer, with periodically arranged and spaced-apart openings. The light incident on the coupling grating structure can be efficiently coupled into the light guide by the spacing between protrusions or by the openings.

According to at least one embodiment, the incoupling structure comprises at least one dichroic coating on a surface of the light guide. The surface may be an outer surface of the light guide, but may also be an inner surface of the light guide. In particular, if the light guide comprises several beam combiner elements, these can have a dichroic coating to allow light of certain wavelengths to pass through at a certain angle of incidence and at the same time deflect or reflect light of a different wavelength.

According to at least one embodiment, the laser package further comprises a carrier substrate on which the laser diodes and the reflector module are arranged. In addition, a frame can be arranged on the carrier substrate, which surrounds the laser diodes and the reflector module in a lateral direction and protrudes in a direction perpendicular to the carrier substrate. The laser package can also be encapsulated by means of a cover arranged on the frame.

In the case of a frame, this can also have a light exit opening through which the light emitted by the laser diodes and shaped and deflected by the reflector module can exit the laser package via the light guide.

According to at least one embodiment, the light guide is integrated into the frame or arranged along an inner surface of the frame. In particular, the light guide may be arranged along a longitudinal side of the laser package on or in the inner surface of the frame. According to at least one embodiment, the light guide can also be integrated into a lid or arranged along an inner surface of the lid, which is arranged on the frame and closes the laser package.

As an extension of the light guide, the frame can also have a light exit opening through which the light emitted by the laser diodes and shaped and deflected by the reflector module can exit the laser package via the light guide.

According to at least one embodiment, the laser package for output or fiber termination also comprises a coupling element, which is arranged downstream of the optical fiber and connects to it. The coupling element can, for example, be a so-called “butt-coupling”, in which the light guide can be coupled to an optical fiber outside the laser package, for example. The coupling element can take the form of a fiber connector, for example. A mode converter can also be arranged downstream of the optical fiber instead of or in addition to the coupling element. The mode converter can also be part of the optical fiber, for example.

However, it is also possible for the light to be extracted from the laser package in the form of a free beam. The free beam can have different divergences depending on the mode and color of the emitted light. By extracting light from the laser package in the form of a free beam and then coupling it into a system connected to the laser package, for example, the overall efficiency can be increased compared to a waveguide-fiber coupling into a system connected to the laser package. According to at least one embodiment, the laser package further comprises a coupling element or decoupling element in the form of a collimating or focusing lens, for example. The decoupling element can be arranged downstream of the light guide and, for example, form the light exit opening of the laser package and be integrated into the frame accordingly or be attached to it. It is also possible for the decoupling element to be arranged inside the package downstream of the light guide and for the light emerging from the light guide to be collimated or focused, for example, before it emerges from the light exit opening of the laser package.

It is understood that the individual aspects and features of the above-mentioned embodiments can be combined as desired. For example, various combinations of reflector module (concave reflectors/lens module/meta-optics) and light guide (SOI waveguide/beam combiner elements) are possible. Concave reflectors can be combined with a classic waveguide as well as with classic beam combiner elements. In the same way, the light guide can also be combined with a lens system, whereby in this case particular attention must be paid to the angles for lateral coupling into the light guide.

According to at least one embodiment, a laser package according to the proposed principle is used for projecting the light emitted by the laser diodes into a human eye, in particular in the field of VR or AR applications. Possible uses also include near-to-eye projections in the consumer sector, in particular for VR or AR applications, in the field of automotive LIDAR systems and generally in industrial laser projections.

### BRIEF DESCRIPTION OF THE DRAWINGS

In the following, embodiments of the invention are explained in more detail with reference to the accompanying drawings. They show, in each case schematically,

FIG. 1 a sectional view of a laser package according to some aspects of the proposed principle;

FIG. 2 a sectional view of another embodiment of a laser package according to some aspects of the proposed principle; and

FIG. 3 a sectional view of a further embodiment of a laser package according to some aspects of the proposed principle.

### DETAILED DESCRIPTION

The following embodiments and examples show various aspects and their combinations according to the proposed principle. The embodiments and examples are not always to scale. Likewise, various elements may be shown enlarged or reduced in size in order to emphasize individual aspects. It is understood that the individual aspects and features of the embodiments and examples shown in the figures can be readily combined with each other without affecting the principle of the invention. Some aspects have a regular structure or shape. It should be noted that slight deviations from the ideal shape may occur in practice without, however, contradicting the inventive concept.

In addition, the individual figures, features and aspects are not necessarily shown in the correct size, and the proportions between the individual elements are not necessarily correct. Some aspects and features are emphasized by enlarging them. However, terms such as “above”, “above”, “below”, “below”, “larger”, “smaller” and the like are shown correctly in relation to the elements in the figures. It is thus possible to deduce such relationships between the elements on the basis of the figures.

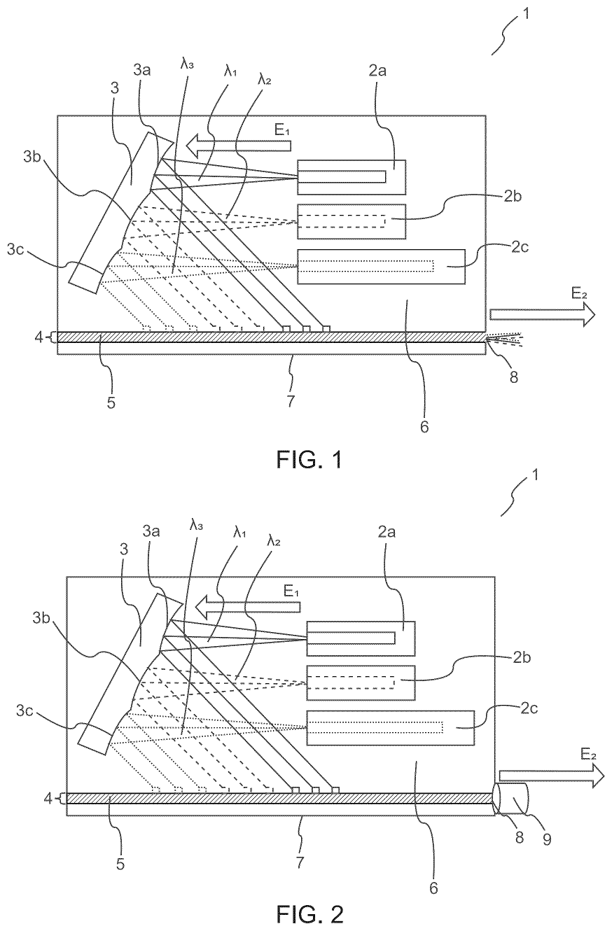

FIG. 1 shows a sectional view of a first embodiment of a laser package 1 according to some aspects of the proposed principle. The laser package 1 comprises a first laser diode 2a for emitting light of a first wavelength λ₁, a second laser diode 2b for emitting light of a second wavelength λ₂ and a third laser diode 2c for emitting light of a third wavelength λ₃. In addition, the laser package 1 comprises a reflector module 3, which is arranged in the beam path of the first, second and third laser diodes 2a, 2b, 2c and which is configured to shape the light of the first, second and third wavelengths λ₁, λ₂, λ₃ emitted by the laser diodes, or as exemplified in the present case, and to redirect it in the direction of a light guide 4 relative to an emission direction E₁ of the first, second and third laser diode 2a, 2b, 2c.

The reflector module 3 has three parabolic sinks 3a, 3b, 3c, which are configured to collimate the light emitted by the first, second and third laser diodes 2a, 2b, 2c of the first, second and third wavelengths λ₁, λ₂, λ₃ separately in each case. The light emitted and collimated by the first, second and third laser diodes 2a, 2b, 2c is additionally deflected by the reflector module, in particular by means of the three parabolic sinks 3a, 3b, 3c, by an angle greater than 90°, in particular by an angle between 90° and 180°, in the direction of the light guide 4.

The optical waveguide 4, in the example shown in the form of a planar waveguide, has an incoupling structure 5 on its surface, which is configured to couple the light deflected by the reflector module 3 in the direction of the waveguide 4 into the waveguide 4. The incoupling structure 5 can, for example, be configured in the form of a coupling grating for the light of the first second and third wavelengths λ₁, λ₂, λ₃ emitted by the first, second and third laser diodes 2a, 2b, 2c. The light of the first second and third wavelengths λ₁, λ₂, λ₃ coupled into the waveguide 4 is superimposed therein and is guided towards a light exit opening 8 at the right-hand end of the waveguide 4.

The superimposed light of the first second and third wavelengths λ₁, λ₂, λ₃ leaves the laser package via the light exit aperture 8 in the form of a free beam in the case shown. The emission direction E₂ of the superimposed light runs in the opposite direction to the emission direction E₁ of the first, second and third laser diode 2a, 2b, 2c due to the deflection of the light by means of the reflector module 3 and the coupling into the waveguide 4, i.e. offset by essentially 180° to the latter. Due to this deflection of the light by essentially 180°, the term “folding of the beam path” is used in the context of this application, whereby the laser package 1 is more compact than a laser package with a serial arrangement of the components used.

The laser package also has a carrier substrate 6 on which the laser diodes 2a, 2b, 2c and the reflector module 3 are arranged. A frame 7 is also arranged on the carrier substrate 6, which surrounds the laser diodes 2a, 2b, 2c and the reflector module 3 in the lateral direction. The first, second and third laser diodes 2a, 2b, 2c are each arranged parallel to one another on the carrier substrate 6 and are configured, for example, in the form of an edge-emitting laser diode, so that they each emit light in the direction of the emission direction E₁.

The waveguide 4 is arranged along an inner side wall of the frame 7, but can also be integrated into it. At the right end of the waveguide, the frame has an opening in which the light exit opening 8 is arranged, through which the light of the first second and third wavelengths λ₁, λ₂, λ₃ superimposed within the waveguide 4 can exit the laser package 1, for example in the form of a free beam.

FIG. 2 shows a sectional view of a further embodiment of a laser package 1 according to some aspects of the proposed principle. In contrast to the embodiment shown in FIG. 1, the laser package also has a coupling element 9, which is arranged downstream of the light exit opening 8 of the waveguide 4 and connects to it. By means of the coupling element 9, it is possible to connect the laser package to an optical fiber into which the superimposed light of the first second and third wavelengths λ₁, λ₂, λ₃ is to be coupled. Instead of the coupling element 9, a mode converter can be arranged downstream of the light outlet opening 8 and connected to it, or the mode converter can be arranged between the coupling element 9 and the waveguide 4 in addition to the coupling element 9.

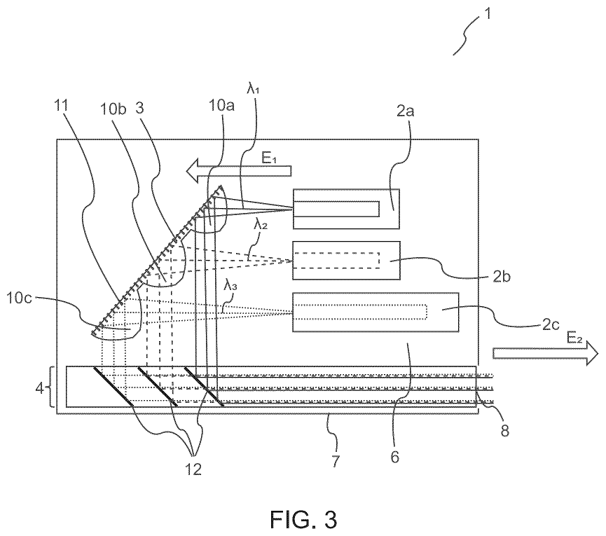

FIG. 3 shows a sectional view of yet another embodiment of a laser package 1 according to some aspects of the proposed principle. The reflector module 3 is configured in the form of a lens system, which comprises three lenses 10a, 10b, 10c arranged next to each other and a reflective coating 11 on a rear side of the lenses. The lenses each have cylindrical entry and exit curvature surfaces for collimating the light emitted by the laser diodes. A reflective coating 11 is provided on the rear side of the lenses to deflect the light emitted by the laser diodes 2a, 2b, 2c. The lenses can, for example, have a common carrier on which they are arranged or, as shown, be manufactured in one piece from one material.

The light guide 4 also has several beam combiner elements 12, by means of which the light of the first second and third wavelengths λ₁, λ₂, λ₃ formed and deflected by the reflector module 3 is guided within the light guide in the direction of the light exit opening 8. The beam combiner elements 12 each have a dichroic coating, due to which the light impinging on a beam combiner element is coupled into the light guide 4. In particular, the dichroic coating can be configured in such a way that it allows light of a certain wavelength to pass through at a certain angle of incidence and simultaneously deflects or reflects light of a different wavelength in the direction of the light exit opening.

1. A laser package comprising:
a first laser diode for emitting light of a first wavelength and at least one second laser diode for emitting light of a second wavelength and
a reflector module which is arranged in the beam path of the first and of the at least one second laser diode, and which is configured to shape the light emitted by the laser diodes and to deflect it by at least 90° in the direction of a light guide with respect to an emission direction (E₁) of the first and of the at least one second laser diode;
wherein the light guide extends substantially parallel to the emission direction (E₁), and
wherein the light guide comprises an incoupling structure which is configured to couple the light deflected by the reflector module in the direction of the light guide into the light guide.

2. The laser package according to claim 1, wherein an emission direction of the laser package is substantially offset by 180° with respect to the emission direction of the first and the at least one second laser diode.

3. The laser package according to claim 1, wherein the first and the at least one second laser diode are arranged parallel to one another.

4. The laser package according to claim 1, wherein the reflector module is configured to separately shape and deflect the light emitted by the first and the at least one second laser diode.

5. The laser package according to claim 1, wherein the reflector module comprises at least two parabolic sinks.

6. The laser package according to claim 1, wherein the reflector module comprises at least two lenses arranged side by side and a reflective coating on a rear side of the lenses.

7. The laser package according to claim 1, wherein the laser package comprises a first, a second and a third laser diode, and wherein the first laser diode is configured to emit red light, the second laser diode is configured to emit green light and the third laser diode is configured to emit blue light.

8. The laser package according to claim 1, wherein the first and the at least one second laser diode are each formed by an edge-emitting laser diode.

9. The laser package according to claim 1, wherein the first and the at least one second laser diode are each formed by a separate laser channel of a multi-ridge laser diode.

10. The laser package according to claim 1, wherein the light guide is formed by a planar waveguide or comprises a plurality of beam combiner elements.

11. The laser package according to claim 1, wherein the incoupling structure comprises a coupling grating structure on a surface of the light guide.

12. The laser package according to claim 1, wherein the incoupling structure comprises a dichroic coating on a surface of the light guide.

13. The laser package according to claim 1, further comprising a carrier substrate on which the laser diodes and the reflector module are arranged, and a frame surrounding the laser diodes and the reflector module in lateral direction.

14. The laser package according to claim 13, wherein the light guide is integrated into the frame or is arranged along an inner surface thereof.

15. The laser package according to claim 1, further comprising a coupling element which is arranged downstream of the light guide and connected thereto.

16. The laser package according to claim 1, further comprising a mode converter downstream of the light guide and connected thereto.

17. A method for use of a laser package according to claim 1 for projecting the light emitted by the laser diodes into a human eye, in particular in the field of VR or AR applications.
